(19) United States
(12) Patent Application Publication
(10) Pub. No.: US 2006/0246336 A1
(43) Pub. Date: Nov. 2, 2006

(54) Electronic circuit board integrated with a fuel cell

(76) Inventors: Hsi-Ming Shu, Taipei (TW); Tsang-Ming Chang, Taipei (TW); Feng-Yi Deng, Taipei (TW)

Correspondence Address: G .LINK Co.,LTD, 3550 Bell Road, MINOOKA, IL, 60447, US

(21) Appl. No.: 11/118,886

(22) Filed: May 2, 2005

(51) Int. Cl. H01M 8/02; H05K 1/14

(52) U.S. Cl. 429/34; 361/784

(57) ABSTRACT

This invention is an electronic circuit board integrated with a fuel cell comprising: a multilayer PCB, including a first region and a second region; an electronic circuit disposed at the first region, including: plural electronic components, disposed at the first region of the multiplayer PCB; plural leads, formed to the first region of the multiplayer PCB, and connecting to the electronic components; a fuel cell disposed at the second region, wherein the multilayer PCB disposed at the second region serves to made a part of the fuel cell.

### FIELD OF THE INVENTION

This invention relates to a fuel cell, particularly to one where the fuel cell and electronic circuits of an electronic machine is integrated to a common PCB.

### BACKGROUND OF THE INVENTION

The conventional fuel cell and electronic machine are of independent units, and the measure for the conventional fuel cell to supply electrical power to the electronic machine is mainly achieved by power line connection, or connectors. Also, the electronic circuit board for the electronic machine, such as the motherboard of a computer, mainly constitutes a PCB, to which plural electronic components and connector, copper foil leads are welded. There has never been any disclosure relevant to fuel cells built-in the electronic circuit board per se.

This invention intends to overcome the shortcoming resulted from the conventional fuel cell and electronic circuit board of the electronic machine being independent units, where no breakthrough has been found for the conventional fuel cell to supply electrical power to the electronic circuit board of the electronic machine, in view of the compact overall design of the electronic circuit board of the electronic machine, and thus discloses an electronic circuit board with a fuel cell integrated to a PCB.

### SUMMARY OF THE INVENTION

A primary objective of this invention is to provide an electronic circuit board with a fuel cell integrated to a PCB.

To achieve the objective of this invention, this invention discloses an electronic circuit board integrated with a fuel cell comprising: a multilayer PCB, including a first region and a second region; electronic circuits disposed at the first region, including: plural electronic components, disposed at the first region of the multiplayer PCB; plural leads, formed to the first region of the multiplayer PCB, and connecting to the electronic components; a fuel cell disposed at the second region, wherein the multilayer PCB disposed at the second region serves to make a part of the fuel cell.

### BRIEF DESCRIPTION OF THE DRAWINGS

These and other modifications and advantages will become even more apparent from the following detained description of a preferred embodiment of the invention and from the drawings in which:

FIG. 1 illustrates a structural schematic view of an electronic circuit board integrated with a fuel cell of this invention; and

FIG. 2 illustrates a structural exploded view of a fuel cell formed to the second region of the multilayer PCB of this invention.

### DETAILED DESCRIPTION OF THE INVENTION

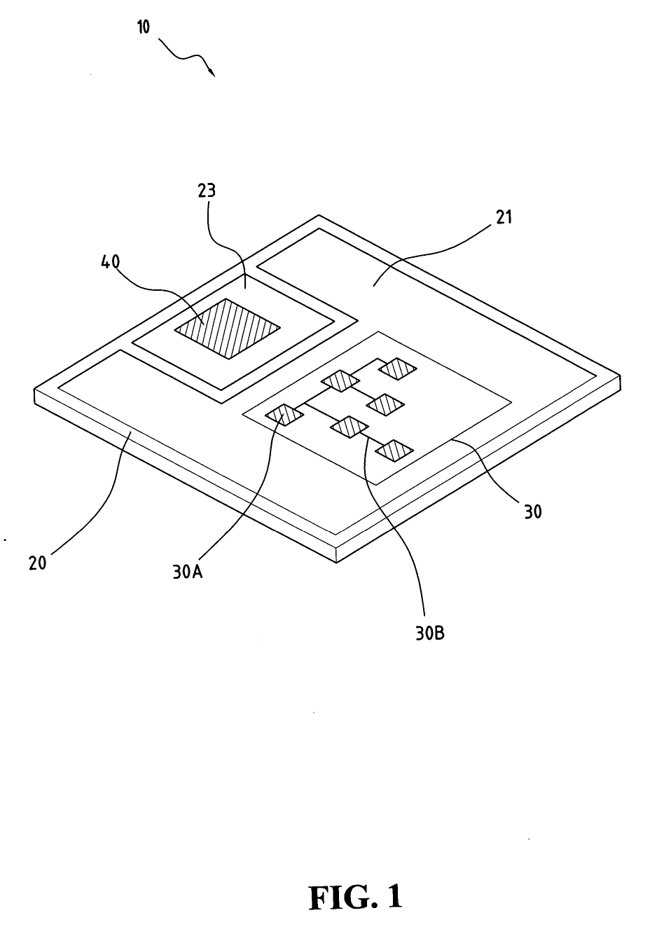

FIG. 1 illustrates a structural schematic view of an electronic circuit board integrated with a fuel cell of this invention; and the electronic circuit board 10 of this invention includes a multilayer PCB 20, electronic circuits 30, and a fuel cell 40. The plural electronic components 30A and plural leads 30B provided to the electronic circuits 30 are all disposed at a first region 21 of the multilayer PCB 20. The measures for disposing these electronic components 30A may be welding, and the leads 30B may be formed to the multilayer PCB by etching or laminated copper foils, where the leads 30B are electrically connected to the electronic components 30A. The fuel cell 40 of this invention may serve as a power supply for supply electrical power to the electronic circuits 30.

In FIG. 1, the fuel cell 40 and the multilayer PCB 20 are combined into a single unit. The fuel cell 40 of this invention is made by adopting the PCB fabrication process. In the process of fabricating the plural leads 30B, the elements required for fabricating the fuel cell 40 is fabricated at the same time, and the elements required by the fuel cell 40 is disposed at a second region 23 of the multilayer PCB 20, so as to achieve the objective of this invention where the primary electronic circuit board 10 can utilize the same multilayer PCB 20 to fabricate the electronic circuits 30 disposed at the first region 21 and the fuel cell 40 disposed at the second region 23.

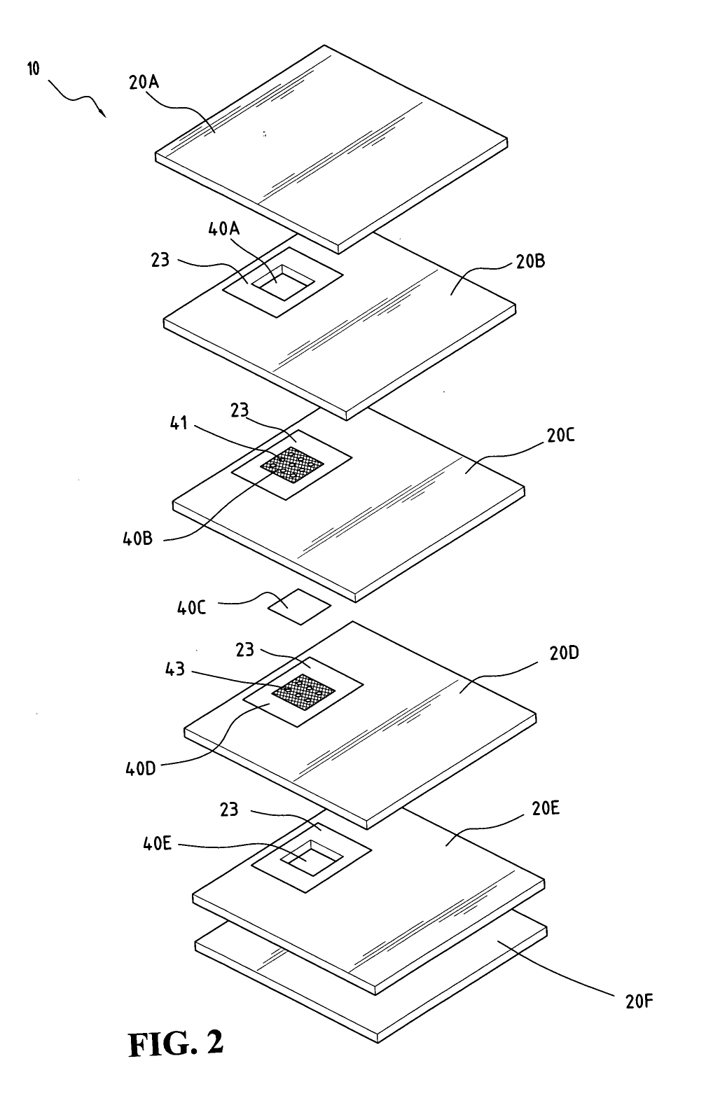

FIG. 2 illustrates a structural exploded view of a fuel cell formed to the second region of the multilayer PCB of this invention. Except for the membrane electrode assembly 40C, other elements of the fuel cell 40 are fabricated by materials originally belonging to the second region 23 of the multilayer PCB 20 by means of PCB fabrication process, such as etching, laser ablation, lamination, and press, so as to form an anode flow field 40A, an anode current collection circuitries 40B, a cathode current collection circuitries 40D and a cathode flow field 40E in each of the single-layer PCB 20B, 20C, 20D, 20E within the second region 23, respectively. Finally, the single-layer PCB 20A, 20B, 20C, 20D, 20E, 20F are pressed together to form a multilayer PCB 20. The membrane electrode assembly 40C is located at the second region 23 and sandwiched between the multilayer PCB 20 at a location corresponding to current collectors 40B, 40D. The membrane electrode assembly 40C may be a membrane electrode assembly for a direct methanol fuel cell.

In a preferred embodiment of the anode flow field 40A and cathode flow field 40E, the single-layer PCB 20B, 20E may each be formed with a hollow region at the second region 23. In a preferred embodiment of the anode current collection circuitries 40B and cathode current collection circuitries 40D, the opposing faces of the single-layer PCB 20C, 20D at the second region 23 may each be formed with meshed copper foils by means of etching or laminated copper foils, and then drilled to form vias 41, 43, wherein a conductive material is applied around a circumferential wall of each of the vias 41, 43, so as allow electrical connection between the meshed copper foils provided to the opposing faces of the single-layer PCB 20C, 20D. The anode fuel at the anode flow field 40A and the cathode fuel at the cathode flow field 40E may each flow through the vias 41, 43, respectively, and then to the positive pole and negative pole of the membrane electrode assembly 40C, to cause electrical chemical reaction of the membrane electrode assembly 40C for generating current, which is collected by the anode current collection circuitries 40B and cathode current collection circuitries 40D, respectively.

The multiplayer PCB 20 of this invention may be an FR4 PCB or a flexible circuit board. In actual applications, the primary electronic circuit board 10 may be a computer motherboard, an electronic circuit board of a portable electronic machine, or an electronic circuit board of other electronic machines.

This invention is related to a novel creation that makes a breakthrough in the art. Aforementioned explanations, however, are directed to the description of preferred embodiments according to this invention. Since this invention is not limited to the specific details described in connection with the preferred embodiments, changes and implementations to certain features of the preferred embodiments without altering the overall basic function of the invention are contemplated within the scope of the appended claims.

What is claimed is:

1. An electronic circuit board integrated with a fuel cell, comprising:
a multilayer PCB, including a first region and a second region;
an electronic circuit disposed at the first region, including:
plural electronic components, disposed at the first region of the multiplayer PCB;
plural leads, formed to the first region of the multiplayer PCB, and connecting to the electronic components;
a fuel cell disposed at the second region, wherein the multilayer PCB disposed at the second region serves to make a part of the fuel cell.

2. The electronic circuit board of claim 1, wherein the electronic circuit board is a computer motherboard.

3. The electronic circuit board of claim 1, wherein the electronic circuit board is an electronic circuit board of a portable electronic machine.

4. The electronic circuit board of claim 1, wherein the fuel cell is a direct methanol fuel cell.

5. The electronic circuit board of claim 1, wherein the fuel cell having at least one membrane electrode assembly sandwiched between the multilayer PCB disposed at the second region.

6. The electronic circuit board of claim 1, wherein the multilayer PCB is selected from an FR4 PCB and a flexible circuit board.

7. The electronic circuit board of claim 1, wherein the fuel cell serves to supply electrical power to the electronic circuits.
